(19) United States
(12) Patent Application Publication
(10) Pub. No.: US 2022/0415862 A1
(43) Pub. Date: Dec. 29, 2022

(54) FULL-COLOR DISPLAY CHIP AND MANUFACTURING PROCESS FOR SEMICONDUCTOR CHIP

(71) Applicant: SUZHOU ULTIVIEW TECHNOLOGY CO., LTD., Suzhou (CN)

(72) Inventor: Tao Zhu, Suzhou (CN)

(21) Appl. No.: 17/777,860

(22) PCT Filed: Dec. 5, 2019
(86) PCT No.: PCT/CN2019/123442

§ 371 Date: May 18, 2022

(51) Int. Cl. H01L 25/075; H01L 33/38; H01L 33/32; H01L 33/62; H01L 33/00

(52) U.S. Cl. CPC H01L 25/0753; H01L 33/382; H01L 33/32; H01L 33/62; H01L 33/005; H01L 2933/0016; H01L 2933/0066

(57) ABSTRACT

A full-color display chip and a manufacturing process for a semiconductor chip. The full-color display chip comprises: a substrate, supporting an array of a pixel driver, a plurality of pairs of anode contact points of the pixel driver and cathode contact points of the pixel driver being arranged on the substrate; and two or more layers, stacked on the top of the substrate and the pixel driver, each layer comprising a micro LED light-emitting structure, each layer of LED light-emitting structure being provided with an anode electrode in conduction with the anode contact points and a cathode electrode in conduction with the cathode contact points, and two adjacent layers of LED light-emitting structures being stacked up and down. The full-color display chip may have advantages of low pixel density and a large light-emitting area, and the manufacturing process has the advantages of high interconnection density and small device input.

### TECHNICAL FIELD

The present disclosure relates to the field of semiconductor component manufacturing technologies, and in particular, to a full-color display chip, and further to a manufacturing process for a semiconductor chip capable of manufacturing the full-color display chip.

### BACKGROUND

A display part (a light-emitting element) and a drive part of a micro LED display are generally completed by a bonding process, such as a conventional flip-chip method. However, in order to achieve full color, three-color (RGB) light-emitting elements are required. A conventional bonding process is only suitable for monochrome display manufacturing.

The Chinese invention patent application with Publication Number CN110462850A discloses a micro LED display chip and a method for manufacturing a micro LED display chip. The display chip includes a substrate and two or more layers with flat interfaces between adjacent layers, and each layer including an array of a micro LED.

In the above structure, three monochrome (RGB) LEDs arranged side by side in a horizontal direction constitute pixels of the micro LED display, and an area of each monochrome LED is less than ⅓ of a pixel area. Such arrangement has the advantages of a relatively simple bonding process and chip assembly completed through single bonding, but has a disadvantage that pixel density of the process is limited by a limit of a single-layer process. That is, display resolution is only one third of the limit of the single-layer process of the device.

### SUMMARY

In order to solve the above technical problems, a first objective of the present disclosure is to provide a full-color display chip that can reduce pixel density and increase a light-emitting area under a same resolution. A second objective of the present disclosure is to provide a manufacturing process for a semiconductor chip with lower requirements for devices.

In order to achieve the first objective of the present disclosure, the present disclosure adopts the following technical solution. A full-color display chip is provided, including:

a substrate supporting an array of pixel drivers, a plurality of pairs of anode contact points of the pixel driver and cathode contact points of the pixel driver being arranged on the substrate; and

two or more layers stacked on the top of the substrate and the pixel driver, each layer including a micro LED light-emitting structure, LED light-emitting structure of each layer being provided with a cathode electrode in conduction with the anode contact points and an anode electrode in conduction with the cathode contact points.

LED light-emitting structures of two adjacent ones of the layers are stacked up and down.

In the above technical solution, preferably, each of the layers includes a light-transmitting insulation layer located on a light emission side of the LED light-emitting structure.

In the above technical solution, preferably, a lens is further arranged on the insulation layer of the outermost one of the layers.

In the above technical solution, preferably, projections of the LED light-emitting structures of the layers stacked up and down on a plane where the substrate is located partially overlap, and projections of the cathode electrodes and the anode electrodes of the LED light-emitting structures of the layers on the plane where the substrate is located are staggered with each other.

In the above technical solution, preferably, the LED light-emitting structures of different layers produce light of different wavelengths.

In the above technical solution, preferably, the full-color display chip includes three layers, and the LED light-emitting structures of the three layers are configured to provide red light, green light and blue light respectively.

In the above technical solution, preferably, the full-color display chip includes two layers, and the two layers are configured to provide red light and green light respectively, or the two layers are configured to provide red light and blue light respectively.

In the above technical solution, preferably, the LED light-emitting structure is one of an III-V nitride epitaxial structure, an III-V arsenide epitaxial structure, an III-V phosphide epitaxial structure and an III-V antimonide epitaxial structure.

In the above technical solution, preferably, each of the layers further includes a filling material, and the filling material is selected from one or more of silicon oxide, alumina, silicon nitride and an organic transparent adhesive.

In order to achieve the second objective of the present disclosure, the present disclosure adopts the following technical solution. A manufacturing process for a semiconductor chip is provided, including:

S0: providing a substrate supporting an array of pixel drivers, the substrate having a first bonding surface and a plurality of pairs of anode contact points and cathode contact points electrically connected to the array of the pixel drivers and exposed on the first bonding surface;

S1: providing a plurality of stacked layers, the stacked layers each including a base, an LED light-emitting structure formed on the base and a cathode electrode and an anode electrode connected to the LED light-emitting structure;

S2: bonding a bottom layer, and flip-chip bonding the stacked layer of the bottom layer on the substrate, to enable the anode electrode and the cathode electrode of the LED light-emitting structure to be conductively connected to a pair of anode contact points and cathode contact points on the substrate respectively;

S3: punching the bonded stacked layer to form holes through the stacked layer, and filling the holes with metal to form a plurality of electrode metal conductors; and

S4: flip-chip bonding another stacked layer on the stacked layer of the bottom layer, to enable the LED light-emitting structure of the another stacked layer to be superimposed directly above the LED light-emitting structure of the stacked layer of the bottom layer, and enable the anode electrode and the cathode electrode of the LED light-emitting structure of the another stacked layer to be connected to the plurality of electrode metal conductors respectively, and filling and planarizing the another stacked layer;

steps S3 and S4 being repeated until all the stacked layers are bonded.

In the above technical solution, preferably, the stacked layer is formed by:

S11: forming an LED epitaxial layer on a base;

S12: forming an island platform by etching, and reserving an anode extraction point and a cathode extraction point at an outer edge of the island platform;

S13: making metal electrodes on the anode extraction point and the cathode extraction point respectively;

S14: filling a layer of filling material; and

S15: performing surface smoothing so that the anode extraction point and the cathode extraction point are exposed and a second bonding surface is formed.

In the above technical solution, preferably, after each bonding, the base on the stacked layer is removed and a light-transmitting insulation layer is formed on a surface of the stacked layer.

In the above technical solution, preferably, after all the stacked layers are bonded, an optical lens is formed on a surface of the stacked layer at a top layer.

In the above technical solution, preferably, the LED light-emitting structures of the plurality of stacked layers produce light of different wavelengths respectively.

In the above technical solution, preferably, three stacked layers are bonded, and the three stacked layers are sequentially provided with a blue LED light-emitting structure, a green LED light-emitting structure and a red LED light-emitting structure from the bottom up.

In the above technical solution, preferably, the plurality of pairs of anode contact points and cathode contact points on the substrate are arranged on outer sides of the LED light-emitting structures along a circumferential direction.

In the full-color display chip according to the present disclosure, LED light-emitting structures of two adjacent layers are stacked up and down, which, compared with the existing horizontal side-by-side arrangement, can reduce pixel density and increase a light-emitting area, and is suitable for applications of AR/VR and other full-color display devices. Structural improvements thereof bring corresponding improvements on the manufacturing process. Compared with the existing manufacturing process of first bonding and then etching a display chip, the manufacturing process for a semiconductor chip according to the present application is suitable for the industrial manufacturing of full-color display chips by first etching and then bonding.

### BRIEF DESCRIPTION OF THE DRAWINGS

FIG. 1 to FIG. 18b are schematic diagrams illustrating a flow of a manufacturing process for a semiconductor chip according to the present disclosure.

In the drawings, 100R: stacked layer (red); 100B: stacked layer (blue); 100G: stacked layer (green); 11: P-type semiconductor; 12: light-emitting layer; 13: N-type semiconductor; 10: LED light-emitting structure; 14b: anode extraction point; 14A: cathode electrode; 14B: anode electrode; 15: filling material; 16: second bonding surface; 17: light-transmitting insulation layer; 170: lens; 18: metal filler; 18C, 18D, 18E, 18F: metal electrode; 19: base; 200: pixel driver; 20: substrate; 22: first bonding surface; A, B, C, D, E, F: anode/cathode contact point.

### DETAILED DESCRIPTION OF THE EMBODIMENTS

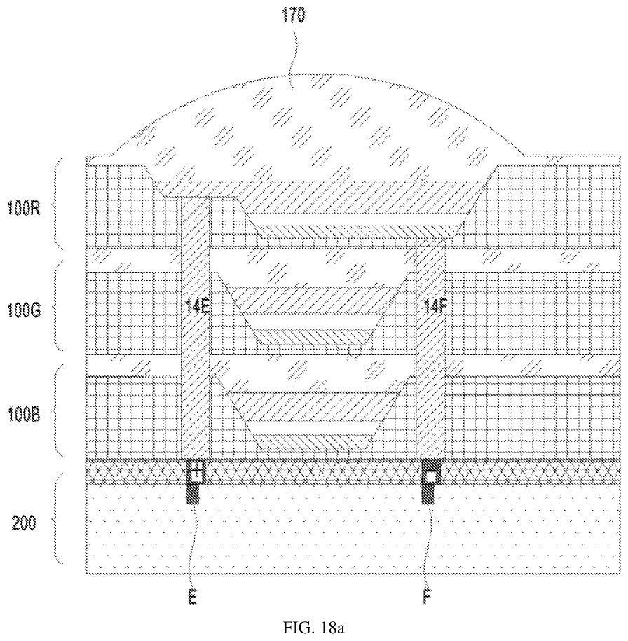

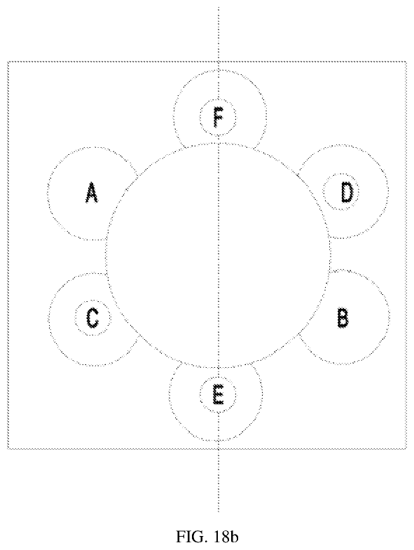

In order to explain the technical content, structural features, objectives achieved and efficacy of the present disclosure in detail, the following is a detailed description with reference to embodiments and the accompanying drawings. The “bottom layer” in the specification corresponds to a lower part in FIG. 18a, the “top layer” corresponds to an upper part in FIG. 18a, the “outer side” in the specification corresponds to an outer side in FIG. 18a, and the center in FIG. 18b corresponds to an “inner side”.

The present disclosure mainly discloses a full-color micro-LED chip, which applied to display screens of AR, VR and other electronic devices, but the present disclosure is not limited to the specific applications mentioned in this embodiment.

FIG. 18a is a sectional view of a full-color display chip according to the present disclosure in a typical embodiment. FIG. 18b is a top view of the full-color display chip. The full-color display chip has a 3-layer structure. In another typical application of the present disclosure, the chip may further be implemented through a 2-layer stack structure.

As can be seen from FIG. 18b, the full-color display chip includes: a substrate 20 and three stacked layers 100R, 100G and 100B.

The substrate 20 is configured to support a pixel driver 200. The substrate 20 may be selected from a silicon-based substrate, a sapphire substrate, a glass substrate or the like. The pixel driver can drive an array of LED light-emitting structures 10 to emit light according to a set rule, so as to present a display image. The pixel driver has a plurality of pairs of anode contact points and cathode contact points of the pixel driver connected to the array of the LED light-emitting structure. FIG. 18a shows that the full-color display chip has three layers of LED light-emitting structures and three anode contact points and three cathode contact points are correspondingly arranged on the substrate, in which A-B are connected to two electrodes of the LED light-emitting structure of the bottom layer, C-D are connected to two electrodes of the LED light-emitting structure of the second layer, and E-F are connected to two electrodes of the LED light-emitting structure of the top layer. The substrate has a first bonding surface 22 on the top layer. The first bonding surface is made of a metal material. The metal material is selected from one of Cu, Al, Au and the like.

The three stacked layers 100R, 100G and 100B are stacked on the top of the substrate 20 and the pixel driver 200. Each of the stacked layers includes a micro LED light-emitting structure 10. LED light-emitting structure 10 of each layer is provided with an anode electrode in conduction with the anode contact points and a cathode electrode in conduction with the cathode contact points. Moreover, LED light-emitting structures 10 of two adjacent layers are vertically stacked up and down. The stacked layers have a same structure and are welded layer by layer by flip-chip bonding. A lens is arranged on a light emission side of the LED light-emitting structure 10 in the uppermost stacked layer.

Since the LED light-emitting structure is transparent, vertical stacking of the plurality of LED light-emitting structures in the present disclosure does not affect light emission of the LEDs. Besides, up and down stacking enables a size of an area of each monochrome pixel to be the same as that of a pixel unit, and thus a pixel area can be maximized, so that the pixel area of the full-color display chip is equal to a light-emitting area of the monochrome LED structure. Correspondingly, the structure of the full-color display chip according to the present disclosure has low requirements for manufacturing devices, and can reduce technological difficulties of monolayer etching, reduce an edge leakage effect of small pixels, and improve the LED light-emitting efficiency. If machined with devices of a generation, the full-color display chip according to the present disclosure can obtain a higher resolution.

Each stacked layer includes a light-transmitting insulation layer 17 located on a light emission side of the LED light-emitting structure. The insulation layer is made of one of silicon oxide, alumina, silicon nitride and an organic transparent adhesive (such as benzocyclobutene). Each of the stacked layers further includes a filling material. The filling material is a non-conductive and non-transparent material, for example, a single compound material such as silicon dioxide or silicon nitride, or a material made from a mixture of a variety of compounds.

The LED light-emitting structure may be selected from any one of an III-V nitride epitaxial structure, an III-V arsenide epitaxial structure, an III-V phosphide epitaxial structure and an III-V antimonide epitaxial structure. Correspondingly, the LED light-emitting structures in different stacked layers produce visible light of different wavelengths respectively. In an embodiment shown in FIG. 18a, a plurality of LED light-emitting structures provide red light, green light and blue light respectively, which are sequentially configured to red, green and blue from top to bottom. In other embodiments, the full-color display chip may optionally have two stacked layers, with two LED light-emitting structures providing red light and green light or red light and blue light respectively.

As shown in FIG. 18b, projections of the LED light-emitting structures in different stacked layers on a plane where the pixel driver is located partially overlap. The LED light-emitting structure may be circular, trapezoid or in other regular or irregular shapes. The plurality of pairs of anode contact points of the pixel driver and cathode contact points on the substrate and anode electrodes and cathode electrodes of the LED light-emitting structures are distributed around a periphery of the overlapping part, so that projections of the cathode electrodes and the anode electrodes of the LED light-emitting structures of the stacked layers on the plane where the pixel driver is located are staggered with each other. A cross section of the LED light-emitting structure may be of any shape and is not necessarily limited to the circular shape in this embodiment.

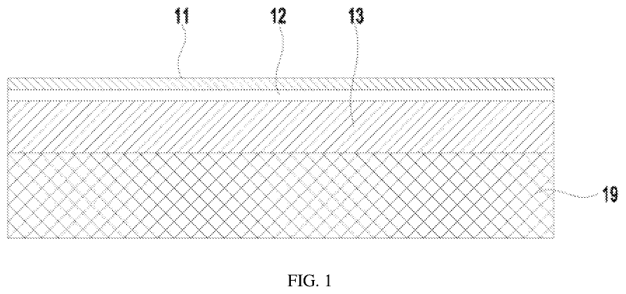

FIG. 1 to FIG. 18b are schematic diagrams illustrating a flow of a manufacturing process for the full-color display chip. The process includes the following steps.

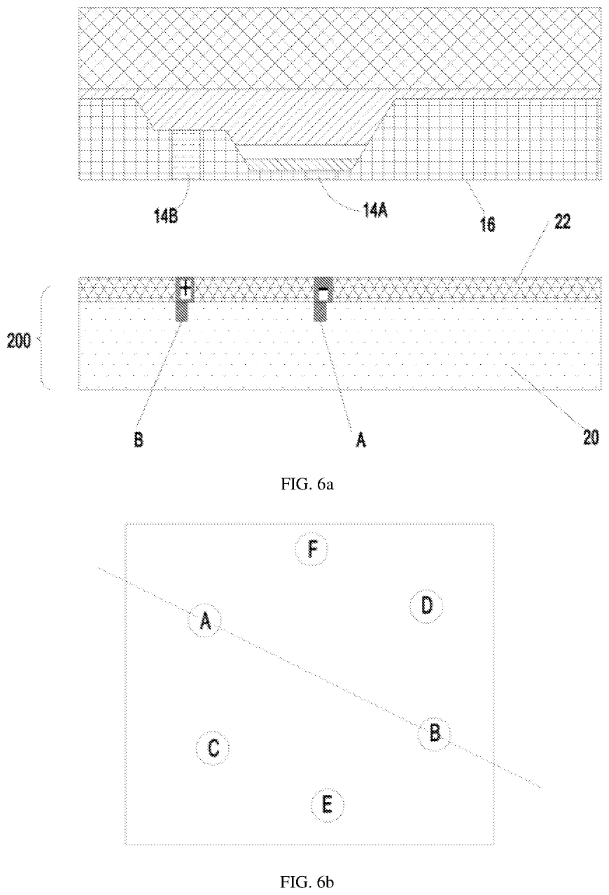

In S0, a substrate is made, which involves making an array of pixel drivers 200 on a silicon-based substrate 20. The substrate has a first bonding surface 22 and three pairs of anode contact points and cathode contact points A, B, C, D, E, F electrically connected to the pixel driver array and exposed on the first bonding surface 22. In this embodiment, a display chip for three primary colors of red, green and blue is taken as an example. Referring to FIG. 6b, in this embodiment, a plurality of pairs of anode contact points and cathode contact points are distributed along a circumference.

In S1, stacked layers 100 are made.

In S11, a GaN-LED epitaxial layer is formed on a sapphire base 19, and the LED epitaxial layer includes an N-type semiconductor layer 13, a light-emitting layer 12 and a P-type semiconductor layer 11, as shown in FIG. 1.

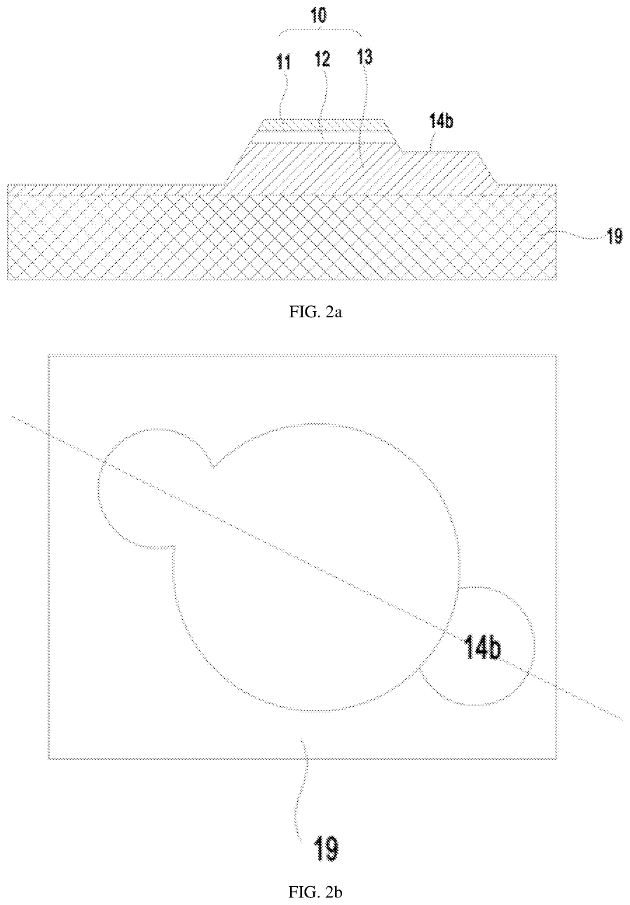

In S12, an island platform is formed by etching, and an anode extraction point 14b and a cathode extraction point are reserved at an outer edge of the island platform. In FIG. 2a and FIG. 2b, 14b is the anode extraction point. FIG. 2b is a schematic top view of a stacked layer, which is only used to show a section position. FIG. 2a is a sectional view taken along the dotted line through Point B in FIG. 2b.

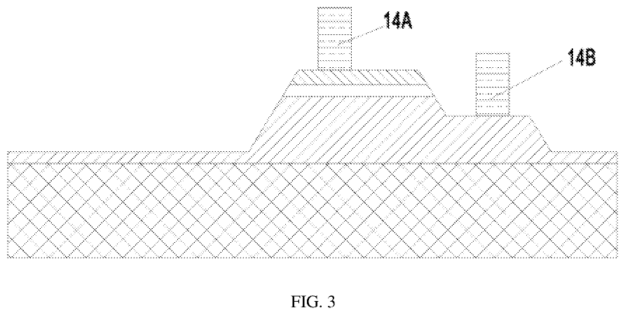

In S13, metal electrodes are made on the anode extraction point 14b and the cathode extraction point respectively to form an anode electrode 14B and a cathode electrode 14A, as shown in FIG. 3.

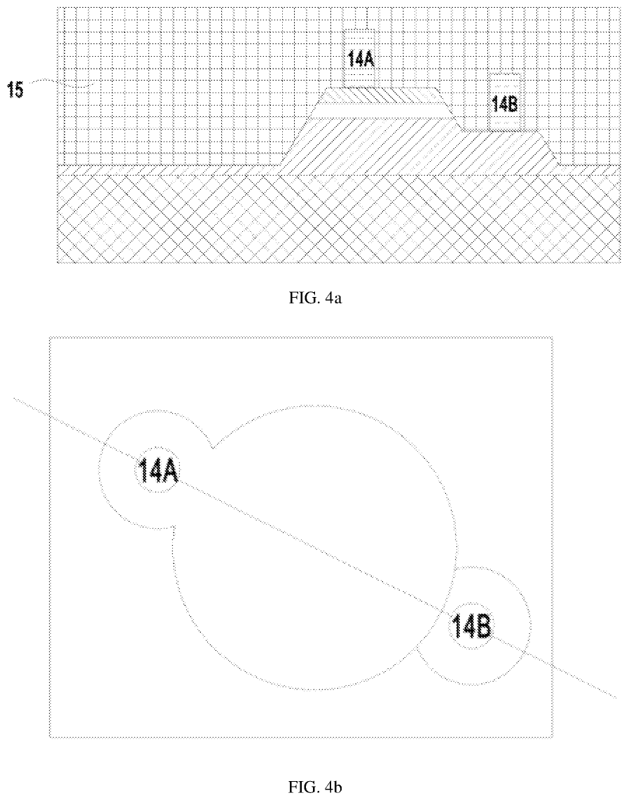

In S14, a layer of filling material 15 is filled, as shown in FIG. 4a. FIG. 4a is a sectional view taken along 14A-14B in FIG. 4b.

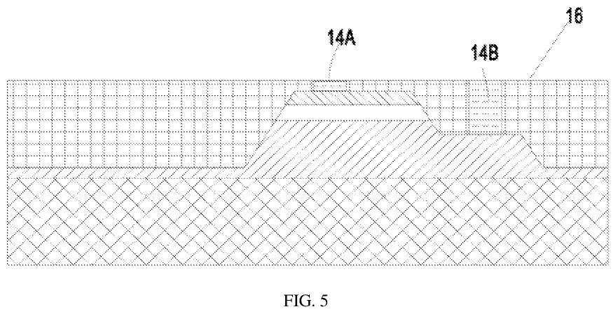

In S15, a semiconductor surface is smoothed by a CMP process, so that the anode electrode 14B and the cathode electrode 14A are exposed and a second bonding surface 16 is formed, as shown in FIG. 5.

According to the above method, a stacked layer 100R with a red LED light-emitting structure, a stacked layer 100G with a green LED light-emitting structure and a stacked layer 100B with a blue LED light-emitting structure are made respectively for use.

In S2, bonding is performed.

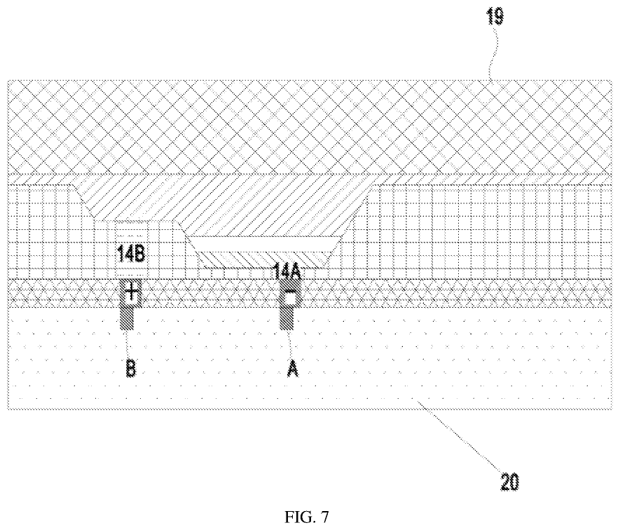

In S21, the stacked layer 100B at a bottom layer is flip-chip bonded on the substrate, so that the first bonding surface 22 and the second bonding surface 16 are welded together, and the anode electrode 14B and the cathode electrode 14A of the LED light-emitting structure of the bottom layer respectively form conductive connections to the anode contact point B and the cathode contact point electric A on the substrate, referring to FIG. 6a and FIG. 6b, forming a semiconductor structure shown in FIG. 7.

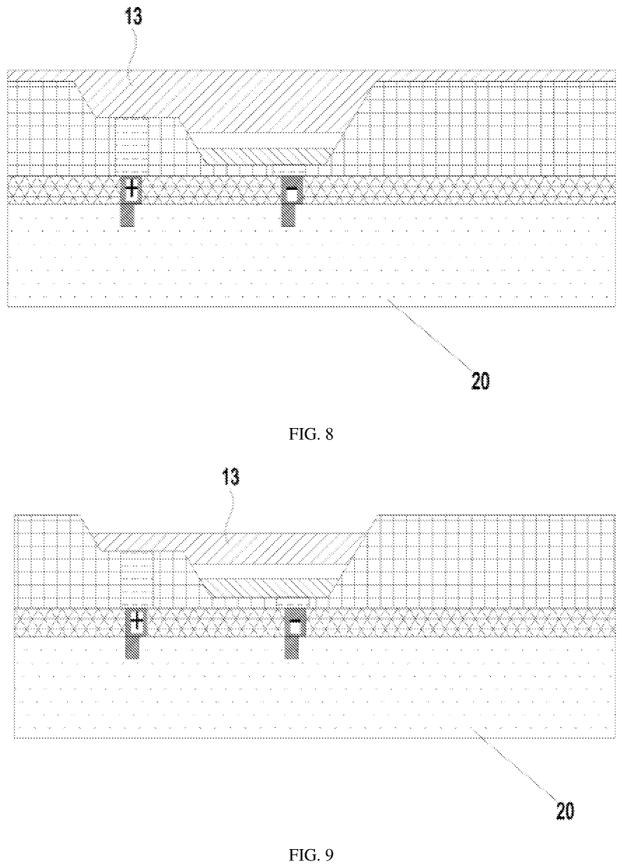

In S22, the sapphire base 19 on the stacked layer 100B is stripped by laser, referring to FIG. 8.

In S23, part of a GaN material is removed by dry etching, so that part of the epitaxial layer is recessed relative to the filling material 15, forming the structure as shown in FIG. 9.

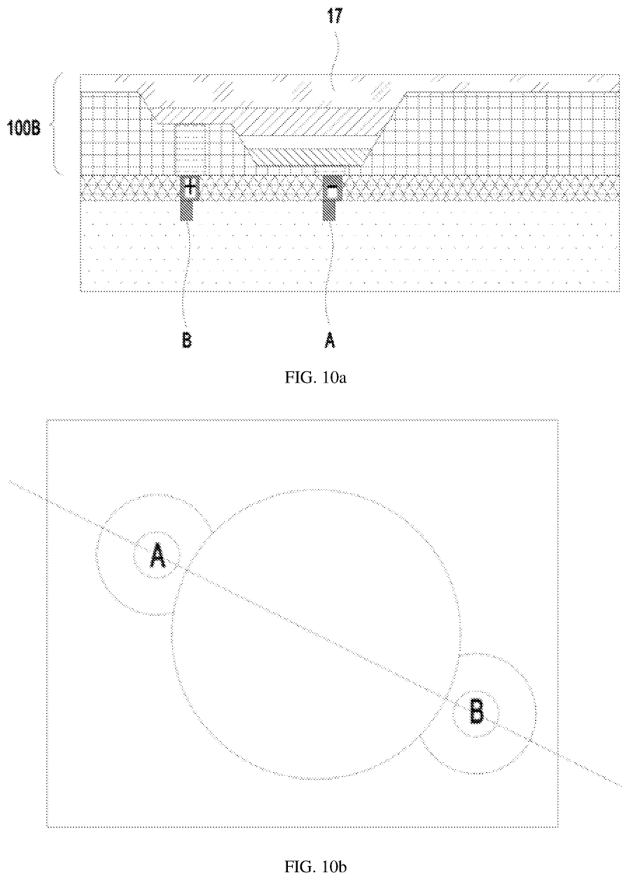

In S24, a light-transmitting insulation layer 17 is formed on the surface, referring to FIG. 10a and FIG. 10b.

In S3, punching is performed.

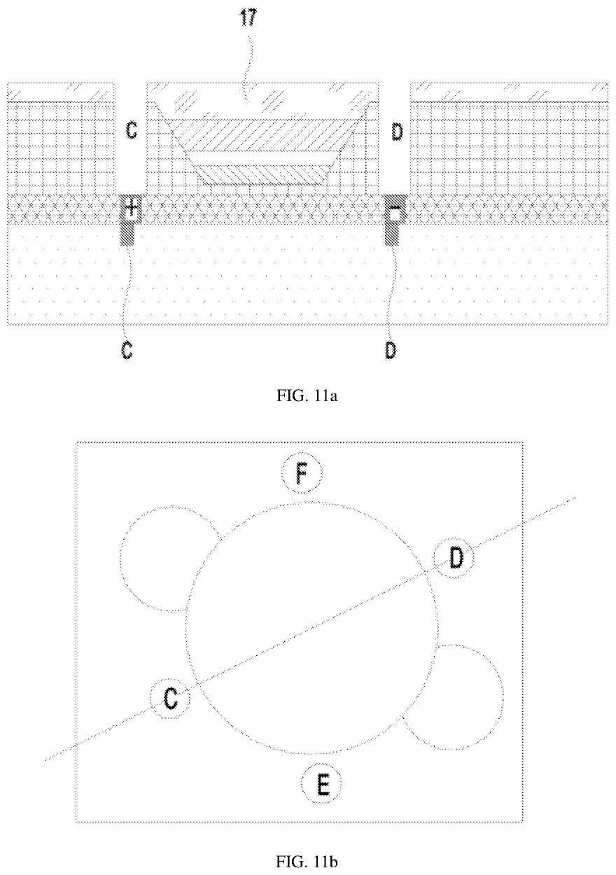

In S31, the stacked layer at the bottom layer is punched by a TSV process, to form holes through the stacked layer at the bottom layer to all the remaining anode contact points and cathode contact points. FIG. 11a and FIG. 11b show a cross-sectional structure taken along a C-D section. The cross-sectional structure taken along a connection of E-F in FIG. 11b is the same as the cross-sectional structure in FIG. 11a.

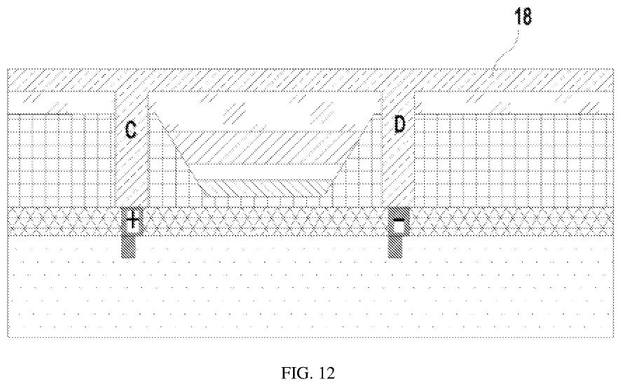

In S32, the holes are filled with a metal filler 18, referring to FIG. 12.

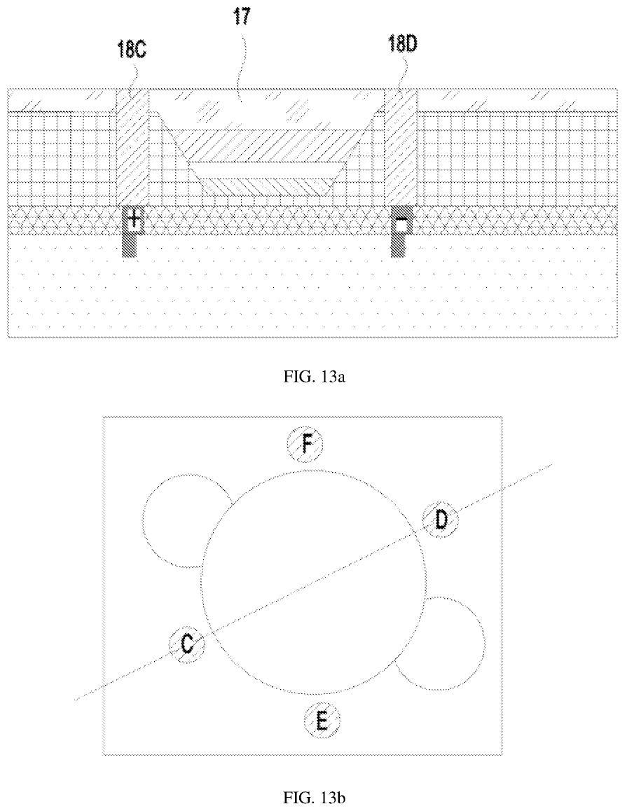

In S34, surface smoothing is performed by the CMP process, so that the light-transmitting insulation layer 17 and the metal electrodes 18C and 18D are exposed, referring to FIG. 13a and FIG. 13b.

In S4, bonding is repeated.

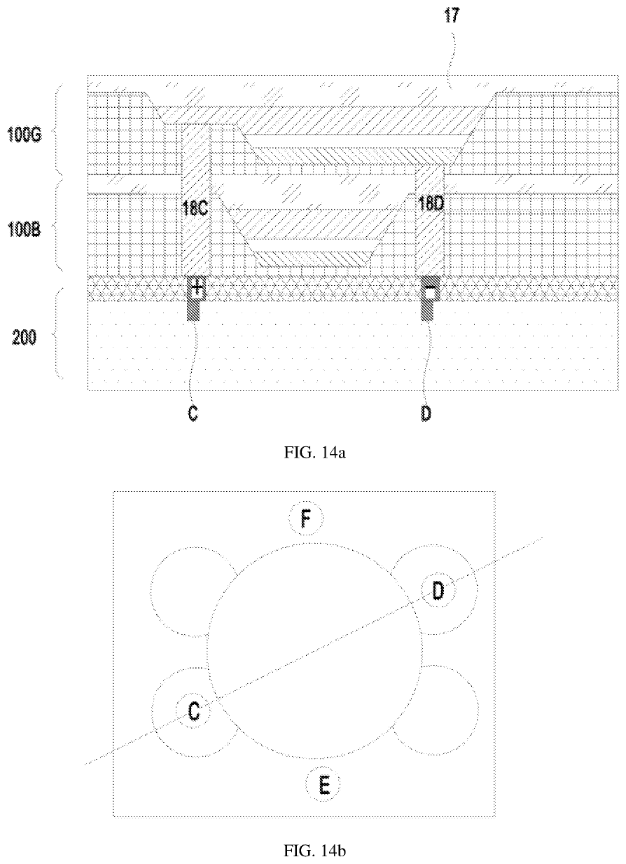

In S41, the green stacked layer 100G is flip-chip bonded on the blue stacked layer 100B, so that the anode electrode and the cathode electrode of the LED light-emitting structure 10 on the green stacked layer 100G are connected to the metal electrodes 18C and 18D passing through the blue stacked layer 100B respectively and form conductive connections to the anode/cathode contact points C and D on the substrate respectively, referring to FIG. 14a and FIG. 14b.

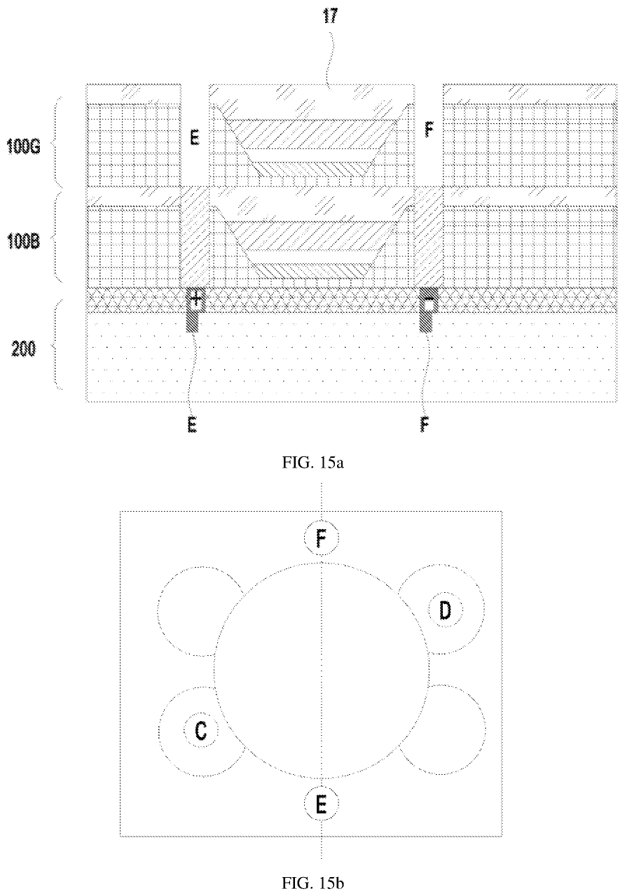

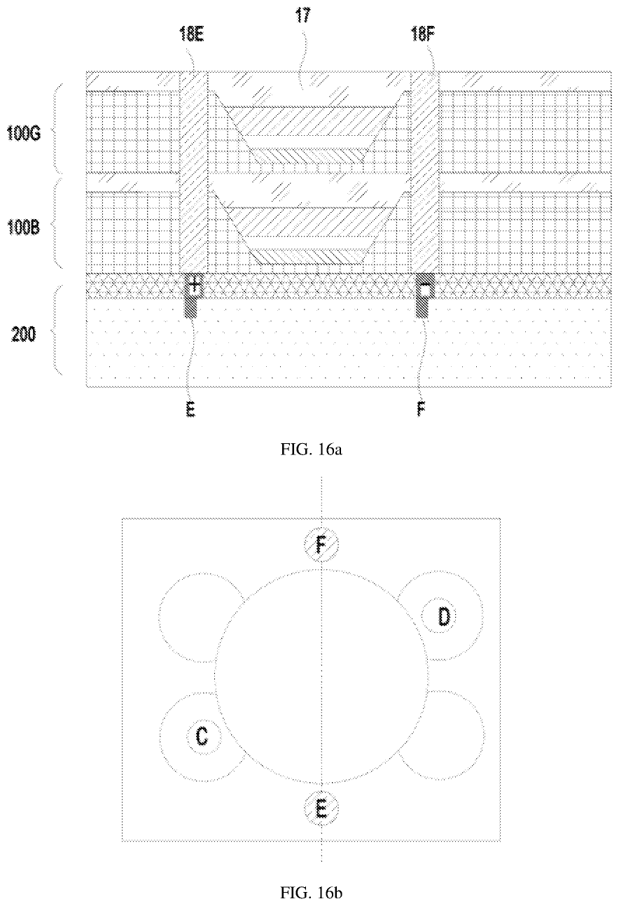

Steps S31 to S34 are repeated, and the green stacked layer 100G is punched to form through holes E and F through the green stacked layer 100G, referring to FIG. 15a and FIG. 15b. The punching part is filled with a metal electrode material, as shown in FIG. 16a and FIG. 16b.

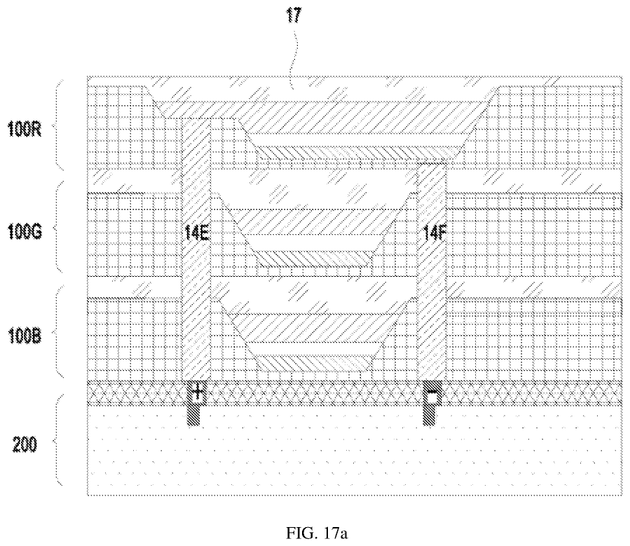

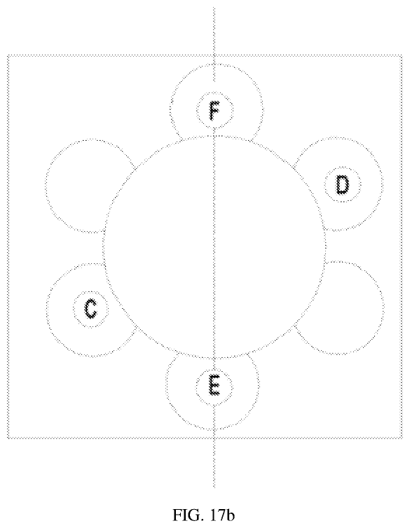

Step S41 is repeated to flip-chip bond the red stacked layer 100R on the green stacked layer 100G, so that the electrodes 18E and 18F of the LED light-emitting structure on the red stacked layer 100R are conductively connected to the electrode contact points E and F on the substrate respectively, referring to FIG. 17a and FIG. 17b.

Finally, after the bonding of the red stacked layer 100R, an optical lens 170 protruding from the insulation layer on the top layer is formed on a surface of the red stacked layer 100R, referring to FIG. 18a and FIG. 18b.

The present disclosure provides a manufacturing process for a semiconductor chip, which has a good color display effect, and can achieve an effect of reducing pixel density and increasing a light-emitting area through multiple bonding.

The above embodiments only illustrate the technical conception and characteristics of the present disclosure, and are intended to enable those skilled in the art to understand the contents of the present disclosure and implement them, without limiting the protection scope of the present disclosure. Any equivalent change or modification made in accordance with the spirit of the present disclosure shall fall within the protection scope of the present disclosure.

1. A full-color display chip, comprising:
a substrate supporting an array of pixel drivers, a plurality of pairs of anode contact points of the pixel driver and cathode contact points of the pixel driver being arranged on the substrate; and
two or more layers stacked on the top of the substrate and the pixel driver, each of the two or more layers comprising a micro LED light-emitting structure, an LED light-emitting structure of each of the two or more layers being provided with a cathode electrode in conduction with the anode contact points and an anode electrode in conduction with the cathode contact points,
wherein LED light-emitting structures of two adjacent ones of the two or more layers are stacked up and down.

2. The full-color display chip according to claim 1, wherein each of the two or more layers includes a light-transmitting insulation layer located on a light emission side of the LED light-emitting structure.

3. The full-color display chip according to claim 2, wherein a lens is further arranged on the light-transmitting insulation layer of the outermost one of the two or more layers.

4. The full-color display chip according to claim 1, wherein projections of the LED light-emitting structures of the two or more layers stacked up and down on a plane where the substrate is located partially overlap, and projections of the cathode electrodes and the anode electrodes of the LED light-emitting structures of the layers on the plane where the substrate is located are staggered with each other.

5. The full-color display chip according to claim 1, wherein the LED light-emitting structures of different layers of the two or more layers produce light of different wavelengths.

6. The full-color display chip according to claim 5, wherein the full-color display chip includes three layers, and the LED light-emitting structures of the three layers are configured to provide red light, green light and blue light respectively.

7. The full-color display chip according to claim 5, wherein the full-color display chip includes two layers, and the two layers are configured to provide red light and green light respectively, or the two layers are configured to provide red light and blue light respectively.

8. The full-color display chip according to claim 1, wherein the LED light-emitting structure is one of an III-V nitride epitaxial structure, an III-V arsenide epitaxial structure, an III-V phosphide epitaxial structure, or an III-V antimonide epitaxial structure.

9. The full-color display chip according to claim 1, wherein each of the two or more layers further includes a filling material, and the filling material is selected from one or more of silicon oxide, alumina, silicon nitride, or an organic transparent adhesive.

10. A manufacturing process for a semiconductor chip, the manufacturing process comprising:
S0: providing a substrate supporting an array of pixel drivers, the substrate having a first bonding surface and a plurality of pairs of anode contact points and cathode contact points electrically connected to the array of the pixel drivers and exposed on the first bonding surface;
S1: providing a plurality of stacked layers, the plurality of stacked layers each including a base, an LED light-emitting structure formed on the base and a cathode electrode and an anode electrode connected to the LED light-emitting structure;
S2: bonding a bottom layer, and flip-chip bonding the stacked layer at the bottom layer on the substrate, to enable the anode electrode and the cathode electrode of the LED light-emitting structure to be conductively connected to a pair of anode contact points and cathode contact points on the substrate respectively;
S3: punching the bonded stacked layer to form holes through the stacked layer, and filling the holes with metal to form a plurality of electrode metal conductors; and
S4: flip-chip bonding another stacked layer on the stacked layer of the bottom layer, to enable the LED light-emitting structure of the another stacked layer to be superimposed directly above the LED light-emitting structure of the stacked layer of the bottom layer, and enable the anode electrode and the cathode electrode of the LED light-emitting structure of the another stacked layer to be connected to the plurality of electrode metal conductors respectively, and filling and planarizing the another stacked layer; and
steps S3 and S4 being repeated until all the stacked layers are bonded.

11. The manufacturing process according to claim 10, wherein the stacked layer is formed by:
S11: forming an LED epitaxial layer on a base;
S12: forming an island platform by etching, and reserving an anode extraction point and a cathode extraction point at an outer edge of the island platform;
S13: making metal electrodes on the anode extraction point and the cathode extraction point respectively;
S14: filling a layer of filling material; and
S15: performing surface smoothing so that the anode extraction point and the cathode extraction point are exposed and a second bonding surface is formed.

12. The manufacturing process according to claim 11, wherein, after each bonding, the base on the stacked layer is removed and a light-transmitting insulation layer is formed on a surface of the stacked layer.

13. The manufacturing process according to claim 10, wherein, after all the stacked layers are bonded, an optical lens is formed on a surface of the stacked layer at a top layer.

14. The manufacturing process according to claim 10, wherein the LED light-emitting structures of the plurality of stacked layers produce light of different wavelengths respectively.

15. The manufacturing process according to claim 10, wherein three stacked layers are bonded, and the three stacked layers are sequentially provided with a blue LED light-emitting structure, a green LED light-emitting structure and a red LED light-emitting structure from the bottom up.

16. The manufacturing process according to claim 10, wherein the plurality of pairs of anode contact points and cathode contact points on the substrate are arranged on outer sides of the LED light-emitting structures along a circumferential direction.
